(19) United States
(12) Patent Application Publication
(10) Pub. No.: US 2026/0147021 A1
(43) Pub. Date: May 28, 2026

(54) CURRENT SENSOR

(71) Applicant: Alps Alpine Co., Ltd., Tokyo (JP)

(72) Inventors: Manabu TAMURA, Miyagi-ken (JP); Takahiro MAGOME, Miyagi-ken (JP); Minoru ABE, Miyagi-ken (JP)

(21) Appl. No.: 19/453,567

(22) Filed: Jan. 20, 2026

Related U.S. Application Data
(63) Continuation of application No. PCT/JP2024/006643, filed on Feb. 22, 2024.

(30) Foreign Application Priority Data
Aug. 2, 2023 (JP) 2023-126156

(51) Int. Cl. G01R 15/20; G01R 19/00

(52) U.S. Cl. CPC G01R 15/205; G01R 19/0092

(57) ABSTRACT

A current sensor according to the present invention includes a bus bar through which a measurement-target current is to flow, a magnetic sensor provided facing the bus bar and configured to detect a magnetic force generated by the bus bar, and a housing including a case and a cover. The bus bar is held between the case and the cover. The housing includes a bus-bar-securing part made of a metal material. The bus bar is in contact with the bus-bar-securing part and is fixed to the bus-bar-securing part.

### CLAIM OF PRIORITY

This application is a Continuation of International Application No. PCT/JP2024/006643 filed on February 22, 2024, which claims benefit of Japanese Patent Application No. 2023-126156 filed on August 2, 2023. The entire contents of each application noted above are hereby incorporated by reference.

### BACKGROUND OF THE INVENTION

### 1. Field of the Invention

The present invention relates to a current sensor configured to measure a measurement-target current flowing through a bus bar.

### 2. Description of the Related Art

In recent years, to control a power source system of a vehicle or the like including various devices, a current sensor configured to measure a measurement-target current flowing through such devices has been in use. A known current sensor includes a magnetic-flux core configured to collect magnetic flux lines and having a hole, through which a bus bar needs to be passed. Such a configuration involves a problem of difficulty in size reduction. Accordingly, various current sensors including no magnetic-flux cores have been proposed.

Japanese Unexamined Patent Application Publication No. 2010-243440 discloses a structure for attaching a current detection device that is suitable for size reduction of the current detection device. The structure includes a cover having a protrusion, a bus bar having a hole through which the protrusion of the cover is to be passed, and a housing having in the lower face thereof a hole. When the bas bar is set to be held between the cover and the housing, the hole of the housing is fitted onto the protrusion passed through the hole of the bus bar.

Japanese Unexamined Patent Application Publication No. 2014-85251 discloses a current sensor that requires neither a case for securing a magnetic object and a magnetosensitive element nor to seal them. The current sensor includes a magnetosensitive element mounted on a substrate, and first and second magnetic objects. Furthermore, a spacer is provided on one face of the substrate. The first and second magnetic objects are secured to each other by a securing component with the substrate and the spacer being interposed in between.

Japanese Unexamined Patent Application Publication No. 2020-128961 discloses a current sensor intended to detect an electric current with high accuracy. The current sensor includes a substrate cooperating with a housing in such a manner as to hold a plurality of bus bars in between, the substrate being secured to the housing; and a securing part securing the substrate to the housing.

### SUMMARY OF THE INVENTION

The current detection device and the current sensors disclosed in Japanese Unexamined Patent Application Publications No. 2010-243440, No. 2014-85251, and No. 2020-128961 are each configured to measure a current value by detecting through a magnetic detection part thereof a magnetic field generated with an electric current flowing through the bus bar. Furthermore, the current detection device and the current sensors each have a structure in which the bus bar is secured by being held between a case and a cover. In such a structure, however, the bus bar has some play with respect to the case. Such play may displace the bus bar. That is, the bus bar tends to be displaced relative to the case. The case is provided with a magnetic detection part at such a position as to face the bus bar. Therefore, if the bus bar is displaced relative to the case, the bus bar is displaced relative to the magnetic detection part. Consequently, a problem arises in that the displacement of the bus bar tends to vary the measurement accuracy of the current sensor. The problem of variation in the measurement accuracy due to the displacements is particularly pronounced in a current sensor including no magnetic-flux core.

If the bus bar is insert-molded in a housing such as a case, the positional relationship between the housing and the bus bar is fixed. Accordingly, the above displacements are suppressed, and a current sensor exhibiting a favorable measurement accuracy is provided. Nevertheless, many of customers' needs regarding current sensors relate to the shape of two end portions of the bus bar to be connected to relevant devices. Therefore, components including the housing need to be adapted for individual bus bars having various shapes. Specifically, since a power source system of a vehicle or the like has a limited space for the installation of a current sensor, the current sensor (the housing thereof) needs to be installed in a permitted area and/or the directions in which two ends of the bus bar to be connected to relevant devices are guided need to be changed. Furthermore, if connection parts of devices to be connected to the bus bar have different shapes, the shape of the bus bar may need to be adapted. That is, the configuration in which the bus bar is insert-molded in the housing increases the manufacturing cost of the current sensor.

Accordingly, the present invention provides a current sensor that is standardized for bus bars having various shapes and in which the displacement of the bus bar relative to the case is suppressed, so that a favorable measurement accuracy is achieved.

According to an aspect of the present invention, a current sensor includes a bus bar through which a measurement-target current is to flow; a magnetic sensor provided facing the bus bar and configured to detect a magnetic force generated by the bus bar; and a housing including a case and a cover, the bus bar being held between the case and the cover. The housing includes a bus-bar-securing part made of a metal material. The bus bar is in contact with the bus-bar-securing part and is fixed to the bus-bar-securing part.

The bus-bar-securing part may be included in the case. Since the bus bar is fixed to the bus-bar-securing part, the positional relationship between the bus bar and the housing is fixed, even without insert-molding the bus bar into the housing. Thus, the displacement between the bus bar and the housing is prevented.

The bus bar may be welded to the bus-bar-securing part. If the bus bar is welded to the bus-bar-securing part, the bus bar is assuredly fixed to the housing.

The bus-bar-securing part may include a projection projecting to an outside of the housing. Furthermore, the bus bar may be fixed to the projection of the bus-bar-securing part by welding.

If the bus bar and the bus-bar-securing part are welded to each other at the projection of the bus-bar-securing part, heat generated at the time of welding is released to the outside of the housing through the projection projecting to the outside of the housing. Accordingly, the risk of deformation of the housing due to heat generated at the time of welding is reduced.

The bus-bar-securing part may be provided at a plurality of locations of the housing. If the bus-bar-securing part is provided at a plurality of locations, the fixing of the bus bar to the housing is more stably and assuredly achieved.

The bus-bar-securing part may be insert-molded in the housing. If the bus-bar-securing part is insert-molded into the housing, the bus-bar-securing part is more firmly fixed to the housing. Accordingly, the bus bar is stably and assuredly fixed to the housing via the bus-bar-securing part.

The bus-bar-securing part may include an anchor portion. The anchor portion functions as a retaining structure that prevents the bus-bar-securing part from coming off the housing. Therefore, the bus-bar-securing part is more firmly fixed to the housing.

A magnetic shield may be insert-molded in the case.

The magnetic shield suppresses magnetic noises to the magnetic sensor. Accordingly, the measurement accuracy of the current sensor increases.

The case may have a groove shaped in conformity with an external shape of the bus bar when viewed in a direction in which the bus bar and the magnetic sensor overlap each other. Furthermore, the bus-bar-securing part may be located in the groove. Furthermore, the bus bar may be fixed to the bus-bar-securing part with the bus bar and the groove fitted to each other.

If the housing has a groove shaped in conformity with the external shape of the bus bar, fitting the bus bar into the groove facilitates the positioning of the bus bar. Accordingly, the bus bar is easily secured at a predetermined position of the housing by fitting the bus bar into the groove and fixing the bus bar to the bus-bar-securing part provided in the groove.

The case may have a groove. Furthermore, the bus-bar-securing part may be located in the groove. Furthermore, the bus bar may include a narrowed portion having a first width dimension; and a widened portion having a second width dimension that is greater than the first width dimension. Furthermore, in a direction in which the bus bar extends, the widened portion may be provided on both sides of the narrowed portion with transitional portions connecting the respective widened portions and the narrowed portion to each other. Furthermore, the groove may include restricting portions that are in contact with the respective transitional portions. Furthermore, the bus bar may be fixed to the bus-bar-securing part with the groove and the bus bar fitted to each other and with the transitional portions and the restricting portions being in contact with each other.

Fitting the bus bar into the groove of the housing and bringing the transitional portions of the bus bar into contact with the restricting portions of the groove restricts the bus bar from moving in the direction in which the bus bar extends. Accordingly, the bus bar is easily positioned relative to the case.

When the groove is viewed in a direction in which the bus bar and the magnetic sensor overlap each other, a width dimension of a narrowed-portion-placing part where the narrowed portion is placed may be greater than the width dimension of the narrowed portion.

Fitting the bus bar including the narrowed portion having a smaller width dimension than the narrowed-portion-placing part into the groove, that is, using a single case for bus bars of a plurality of kinds including narrowed portions having different width dimensions, reduces the manufacturing cost of the current sensor.

### BRIEF DESCRIPTION OF THE DRAWINGS

FIG. 1 is a perspective view of bus bars, illustrating variations in the shape of two ends thereof;

FIG. 2 is a perspective view schematically illustrating an appearance of a current sensor according to a first embodiment;

FIG. 3 is an exploded perspective view illustrating a configuration of the current sensor illustrated in FIG. 2;

FIG. 4 is a sectional view schematically illustrating a configuration of relevant part of the current sensor, taken along line IV-IV given in FIG. 2;

FIG. 5A is a sectional view schematically illustrating a modification of the current sensor illustrated in FIG. 4;

FIG. 5B is a perspective view illustrating an exemplary shape of a bus-bar-securing part illustrated in FIG. 5A;

FIG. 5C is a perspective view illustrating an exemplary shape of the bus-bar-securing part illustrated in FIG. 5A;

FIG. 5D is a perspective view illustrating an exemplary shape of the bus-bar-securing part illustrated in FIG. 5A;

FIG. 5E is a perspective view illustrating an exemplary shape of the bus-bar-securing part illustrated in FIG. 5A;

FIG. 6 is a sectional view schematically illustrating a modification of the current sensor illustrated in FIG. 5A;

FIG. 7 is a sectional view schematically illustrating another modification of the current sensor illustrated in FIG. 4;

FIG. 8 is a sectional view schematically illustrating a modification of the current sensor illustrated in FIG. 7;

FIG. 9 is a plan view schematically illustrating a fitting structure between the bus bar and a housing included in the current sensor illustrated in FIG. 4;

FIG. 10 is a plan view schematically illustrating a modification of the fitting structure illustrated in FIG. 9;

FIG. 11 is a plan view schematically illustrating another modification of the fitting structure illustrated in FIG. 9;

FIG. 12 is a plan view schematically illustrating a state where a bus bar including a narrowed portion having a different width dimension from the one illustrated in FIG. 11 is placed at a narrowed-portion-placing part of a case illustrated in FIG. 11;

FIG. 13 is a sectional view schematically illustrating a configuration of a current sensor according to a second embodiment;

FIG. 14 is a sectional view schematically illustrating a modification of the current sensor illustrated in FIG. 13;

FIG. 15 is a sectional view schematically illustrating the current sensor illustrated in FIG. 14 but seen in another direction; and

FIG. 16 is a sectional view schematically illustrating a configuration of a current sensor according to a third embodiment.

### DESCRIPTION OF THE PREFERRED EMBODIMENTS

Embodiments of the present invention will now be described with reference to the accompanying drawings. In the drawings, the same elements are denoted by the same reference signs, and redundant description is omitted as appropriate. To define the positional relationship between relevant elements, the drawings are provided with a reference coordinate system, according to need. In the reference coordinate system, the width direction of the bus bar is defined as the X direction (third direction), a direction that is orthogonal to the X direction and in which the bus bar extends is defined as the Y direction (second direction), and a direction that is orthogonal to the X direction and the Y direction and in which a bus bar and a magnetic sensor overlap each other is defined as the Z direction (first direction). The X direction is the direction of the axis of sensitivity of the magnetic sensor. The Y direction and the Z direction are orthogonal to the axis of sensitivity.

In a magnetic current sensor configured to measure the magnetic force that is generated from a bus bar with the flow of a measurement-target current, displacements of relevant components tend to affect the measurement accuracy. In particular, a displacement between the magnetic sensor and the bus bar leads to a change in the direction of the magnetic field to be measured by the magnetic sensor, and therefore tends to affect the measurement accuracy. The magnetic sensor is secured to a case with no backlash or play. Hence, to prevent the displacement between the case (magnetic sensor) and the bus bar, the related art employs a configuration in in which the bus bar is insert-molded in the case so that the two are integrated with each other.

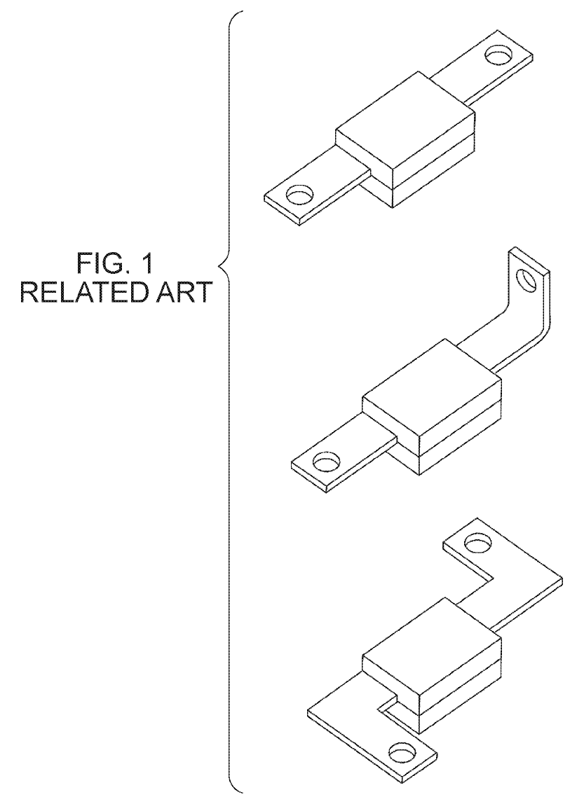

FIG. 1 is a perspective view of bus bars, illustrating variations in the shape of two ends thereof. As illustrated in the drawing, the need for the shape of two end portions of the bus bar tends to vary with customers. Therefore, in many cases, the current sensor is specially adapted for individual customer needs. In other words, there are an increasing number of variations in the shape of the end portions of the bus bar. To manufacture current sensors that meet such variations on the basis of a configuration in which a bus bar is insert-molded in a case, the die for molding needs to be redesigned for the individual variations, which increases the manufacturing cost of the current sensors. Accordingly, instead of insert-molding the bus bar into the housing of the current sensor, if the bus bar and the housing are provided as separate bodies but components other than the bus bar, whose shape varies, are standardized across different customer needs, the manufacturing cost of the current sensor can be reduced.

As a configuration in which the bus bar and the housing are provided as separate bodies, the following may be conceivable: a configuration in which the bus bar is press-fitted into a hole provided in the housing, and a configuration in which the bus bar is held between members constituting the housing. In the former configuration, for example, a bus bar having bent portions at two ends thereof cannot be press-fitted into the hole of the housing. In contrast, the latter configuration is advantageous in being capable of handling a bus bar having bent portions at two ends thereof.

The current sensor according to the present invention employs a configuration in which the bus bar is held between members constituting the housing, thereby handling many kinds of bus bars including a one having a bent portion at an end thereof. With such a configuration, the elements of the current sensor including the bus bar whose shape varies can be standardized except for the bus bar. That is, the necessity of preparing a die for molding the housing for individual variations of the bus bar is eliminated, which suppresses the increase in the manufacturing cost of the current sensor.

### First Embodiment

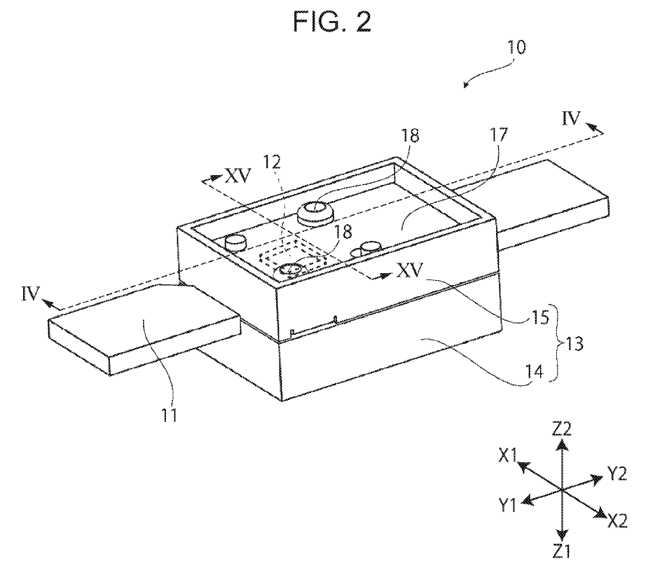

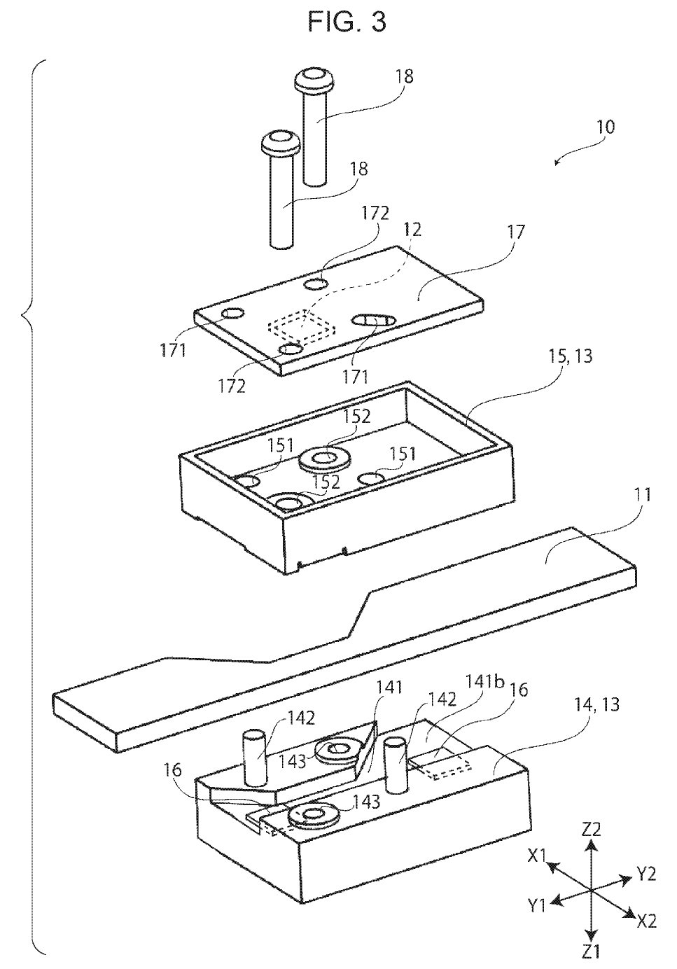

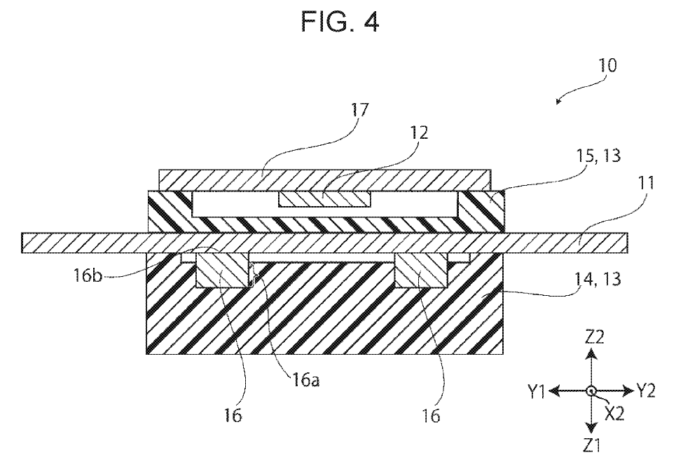

FIG. 2 is a perspective view schematically illustrating an appearance of a current sensor 10 according to a first embodiment. FIG. 3 is an exploded perspective view illustrating a configuration of the current sensor 10 illustrated in FIG. 2. FIG. 4 is a sectional view schematically illustrating a configuration of relevant part of the current sensor 10, taken along line IV-IV given in FIG. 2.

As illustrated in the drawings, the current sensor 10 includes a bus bar 11, a magnetic sensor 12, and a housing 13.

The bus bar 11 is a plate-shaped conductor through which a measurement-target current is to flow. The bus bar 11 is made of, for example, copper, brass, aluminum, or the like.

The magnetic sensor 12 is configured to detect a magnetic force that is generated by the bus bar 11 with the flow of the measurement-target current. The magnetic sensor 12 is provided on a substrate 17 in such a manner as to face the bus bar 11 in the Z direction. The axis of sensitivity of the magnetic sensor 12 extends in the X direction. The magnetic sensor 12 is capable of detecting a magnetic field generated in the X direction. With the detecting surface of the magnetic sensor 12 straightly facing the bus bar 11, the magnetic sensor 12 is able to detect with high accuracy the magnetic force generated as an induction field by the bus bar 11. The detecting element of the magnetic sensor 12 may be a magnetoresistive-effect element, a Hall element, or the like. The above configuration is an example in which a magnetoresistive-effect element is employed as the detecting element of the magnetic sensor 12. If another detecting element is employed, the orientation of the detecting surface and/or other relevant factors need to be changed as appropriate.

While FIG. 3 illustrates a configuration including screws 18 for securing the substrate 17 to the housing 13, the method of securing the substrate 17 to the housing 13 is not limited thereto. For example, the substrate 17 may be secured to the housing 13 by heat crimping, metal crimping, press fitting, soldering, or the like.

The housing 13 includes a case 14 and a cover 15, which are made of resin or the like. The bus bar 11 is held between the case 14 and the cover 15.

The case 14 may have a groove 141 in a counter surface thereof that faces the cover 15. The groove 14 extends in the Y direction. The groove 141 may be shaped in conformity with the shape of a portion of the bus bar 11 that is to be held between the case 14 and the cover 15. With the engagement of the bus bar 11 with the groove 141, the bus bar 11 is positioned relative to the case 14. The case 14 further includes a bus-bar-securing part 16, which may be provided at an inner bottom surface 141b (the inner bottom) of the groove 141. The bus-bar-securing part 16 is made of a metal material. The metal material constituting the bus-bar-securing part 16 may be copper, brass, aluminum, or the like. The bus-bar-securing part 16 includes an embedded portion 16a, which is embedded in the case 14; and a fixing surface 16b, which is exposed at a surface of the case 14 (at the inner bottom surface 141b of the groove 141).

The cover 15 has a function of securing the bus bar 11 by holding the bus bar 11 between the case 14 and the cover 15, and a function of insulating the bus bar 11 and the substrate 17 from each other. FIGS. 2 to 4 illustrate an embodiment in which the cover 15 is present between the bus bar 11 and the substrate 17. If the insulation is achieved by providing a predetermined distance, the cover 15 may have a hole passing therethrough in the Z direction in a portion of or over the entirety of a region that is present between the bus bar 11 and the substrate 17 and/or in a portion of or over the entirety of a region that is present between the bus bar 11 and the magnetic sensor 12.

The fixing surface 16b of the bus-bar-securing part 16 is fixed to a surface of the bus bar 11. With the bus bar 11 and the bus-bar-securing part 16 being in contact with each other, the bus bar 11 is fixed to the fixing surface 16b of the bus-bar-securing part 16 whose embedded portion 16a is embedded in the case 14. Thus, the bus bar 11 is firmly fixed to the case 14 via the bus-bar-securing part 16. Accordingly, the bus bar 11 and the case 14 are prevented from being displaced relative to each other.

The bus bar 11 of the current sensor 10 may be welded to the bus-bar-securing part 16. Welding the bus bar 11 to the bus-bar-securing part 16 assuredly fixes the bus bar 11 to the case 14. Alternatively, the bus bar 11 may be bonded to the bus-bar-securing part 16 with adhesive or the like.

While the bus-bar-securing part 16 of the current sensor 10 is provided at two locations of the case 14, the bus-bar-securing part 16 may be provided at a single location or three or more locations. From the viewpoint of stably and assuredly fixing the bus bar 11 to the case 14, the bus-bar-securing part 16 may preferably be provided at a plurality of locations of the case 14.

The bus-bar-securing part 16 may be insert-molded in the case 14. Insert-molding the bus-bar-securing part 16 into the case 14 firmly secures the bus-bar-securing part 16 (embedded portion 16a) to the case 14. Thus, the bus-bar-securing part 16 contributes to stable and assured fixing of the bus bar 11 to the case 14.

Insert-molding the bus-bar-securing part 16, which is intended to secure the bus bar 11, into the case 14 and fixing the bus bar 11 to the bus-bar-securing part 16 enables various kinds of bus bars 11 having different shapes to be secured to a standardized case 14, eliminating the necessity of insert-molding the bus bar 11 into the case 14.

While the bus-bar-securing part 16 of the current sensor 10 described above is included in the case 14, the present invention may alternatively be embodied with a bus-bar-securing part 16 included in the cover 15.

To summarize, in the current sensor 10, the bus bar 11 is fixed to the bus-bar-securing part 16. Therefore, even without insert-molding the bus bar 11 into the housing 13, the positional relationship between the bus bar 11 and the housing 13 is fixed. Thus, the displacement between the bus bar 11 and the magnetic sensor 12 is prevented. Accordingly, the reduction in the measurement accuracy of the current sensor 10 due to the displacement of the bus bar 11 is suppressed, the use of the standardized housing 13 for bus bars 11 having various shapes is enabled. Consequently, the manufacturing cost of the current sensor 10 is reduced.

Here, a supplementary explanation for the positioning and securing between relevant components according to the present embodiment will be provided with reference to FIG. 3. As described above, with the engagement of the bus bar 11 with the groove 141 provided in the counter surface of the case 14 that faces the cover 15, the bus bar 11 is positioned relative to the case 14. The case 14 has, in addition to the groove 141, two positioning pins 142 at the counter surface thereof that faces the cover 15. The cover 15 has through-holes 151 at locations corresponding to the positioning pins 142. The through-holes 151 have substantially the same external shape and size as the positioning pins 142.

With the positioning pins 142 passed through the through-holes 151, the cover 15 is placed over the case 14, whereby the case 14 and the cover 15 are positioned relative to each other. In this state, the positioning pins 142 passing through the through-holes 151 project from a surface of the cover 15 that is opposite the counter surface facing the case 14. On the opposite surface is placed the substrate 17 carrying the magnetic sensor 12. The substrate 17 also has through-holes 171 at locations corresponding to the positioning pins 142. The positioning pins 142 are to be passed through the through-holes 171. With the positioning pins 142 passed through the through-holes 171, the substrate 17 is placed over the cover 15, whereby the substrate 17 is positioned relative to the cover 15.

Positioning the components as described above positions the bus bar 11 and the magnetic sensor 12 relative to each other. In this state, the screws 18 are passed through the through-holes 172 of the substrate 17 and through-holes 152 of the cover 15 into screw holes 143 of the case 14, whereby the positional relationship between the components is fixed. Thus, the reduction in the measurement accuracy due to the displacement of the bus bar 11 is suppressed.

### Modifications

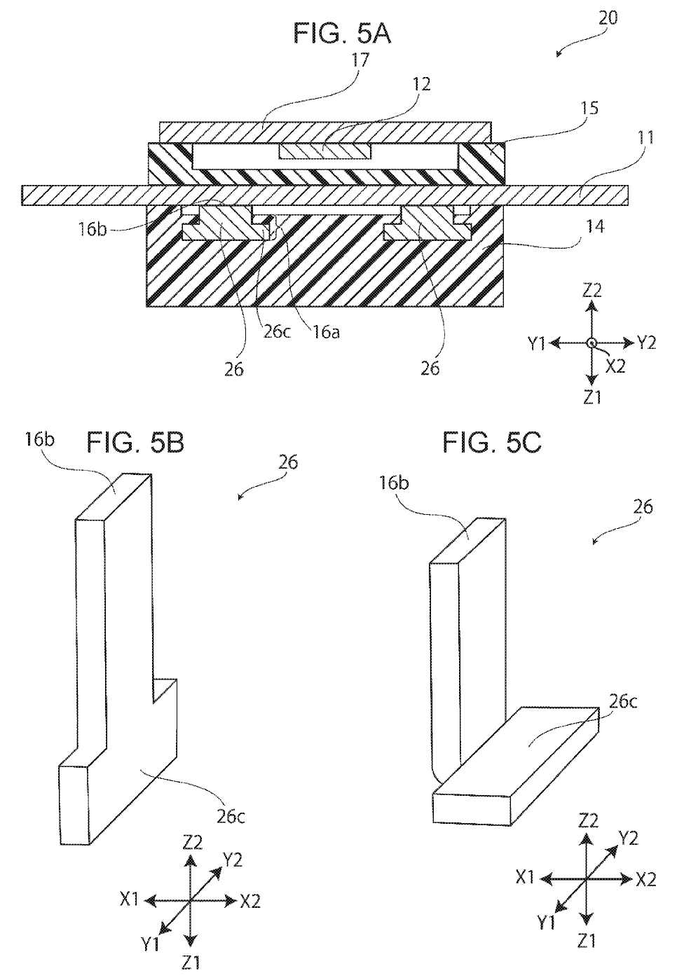

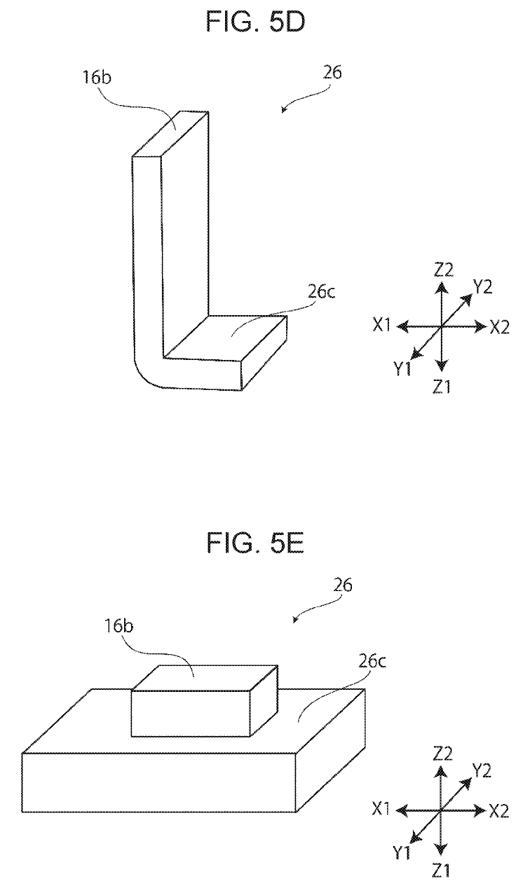

FIG. 5A is a sectional view schematically illustrating a current sensor 20, which is a modification of the current sensor 10 illustrated in FIG. 4. FIGS. 5B to 5E are perspective views illustrating exemplary shapes of a bus-bar-securing part 26, which is included in the current sensor 20 illustrated in FIG. 5A.

The current sensor 20 illustrated in the drawings is the same as the current sensor 10 in that the bus-bar-securing part 26 is insert-molded in the case 14 and in that the bus-bar-securing part 26 includes the embedded portion 16a and the fixing surface 16b. The current sensor 20 is different from the current sensor 10 in that the embedded portion 16a of the bus-bar-securing part 26 includes an anchor portion 26c.

The anchor portion 26c of the bus-bar-securing part 26 projects in the Y direction at an end of the embedded portion 16a on the Z1 side. The resin constituting the case 14 is present on the Z2 side of the anchor portion 26c. Therefore, the anchor portion 26c functions as a retaining structure of the bus-bar-securing part 26. With the anchor portion 26c, the bus bar 11 is more firmly and assuredly secured to the case 14 via the bus-bar-securing part 26.

In terms of low-cost manufacturability, the bus-bar-securing part 26 may preferably have a shape suitable for metal-sheet processing. Examples of such a shape of the bus-bar-securing part 26 include a plate shape illustrated in FIG. 5B having a surface including a widened portion and extending parallel to the Z direction, a plate shape illustrated in FIG. 5C including a widened portion bent to extend in a direction intersecting the Z direction, and a plate shape illustrated in FIG. 5D having a surface extending parallel to the Z direction with a portion near the Z1-side end thereof being bent.

The method of forming the bus-bar-securing part 26 is not limited to metal-sheet processing and may be any other. For example, cutting enables the formation of a bus-bar-securing part 26 having a shape illustrated in FIG. 5E, in which an anchor portion 26c surrounds the Z1-side end of the embedded portion 16a while projecting in the direction of the XY plane.

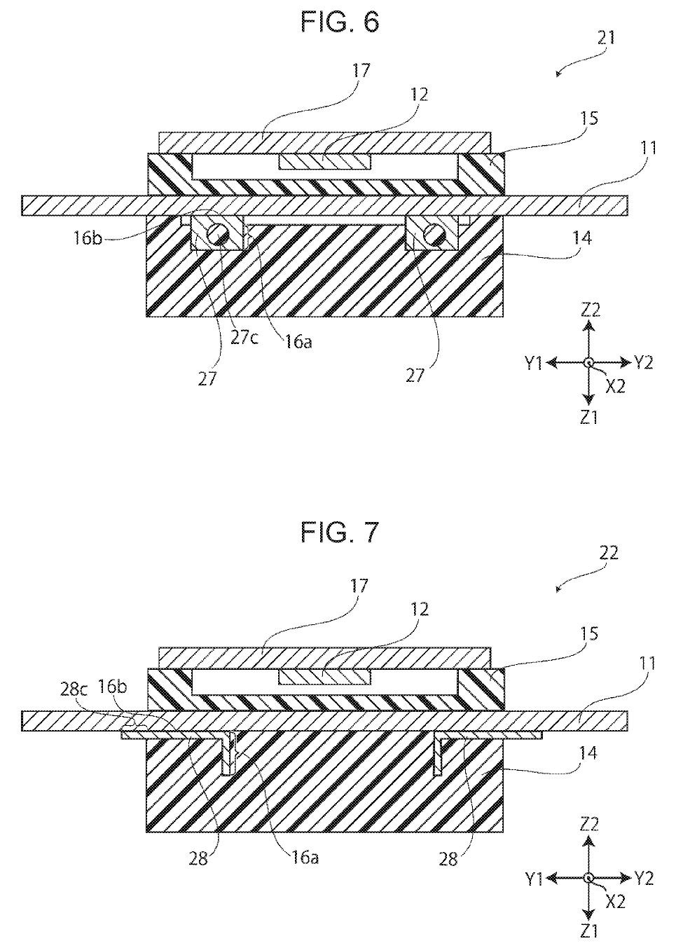

FIG. 6 is a sectional view schematically illustrating a current sensor 21, which is a modification of the current sensor 20 illustrated in FIG. 5A. The current sensor 21 illustrated in the drawing includes a bus-bar-securing part 27, in which an anchor portion 27c provided at the embedded portion 16a has a different configuration from the anchor portion 26c of the bus-bar-securing part 26 of the current sensor 20.

The anchor portion 27c of the bus-bar-securing part 27 is a hole passing through the embedded portion 16a. The entirety or part of the anchor portion 27c is filled with the resin constituting the case 14, whereby the anchor portion 27c functions as a retaining structure of the bus-bar-securing part 27. Thus, the bus bar 11 is more firmly and assuredly secured to the case 14 via the bus-bar-securing part 27.

The anchor portion 27c of the current sensor 21 is only exemplary. The direction of the anchor portion 27c may be a direction other than the X direction. Considering the function of preventing the bus-bar-securing part 27 from coming off the case 14, the anchor portion 27c may preferably be a hole passing through the embedded portion 16a in a direction orthogonal to the Z direction, that is, a direction parallel to the XY plane. Note that the anchor portion 27c may be a hole or a groove that does not pass through the bus-bar-securing part 27. As another alternative, the anchor portion 27c may be a cutout provided at a Y-direction end of the embedded portion 16a.

Since the anchor portions 26c and 27c function as a retaining structure of the respective bus-bar-securing parts 26 and 27, the bus-bar-securing parts 26 and 27 are each more firmly secured to the case 14. With the bus-bar-securing part 26 or 27, the bus bar 11 is firmly fixed to the case 14. Accordingly, the deterioration in the measurement accuracy of the current sensor 20 or 21 due to the displacement of the bus bar 11 relative to the case 14 is suppressed.

FIG. 7 is a sectional view schematically illustrating a current sensor 22, which is another modification of the current sensor 10 illustrated in FIG. 4. As illustrated in the drawing, the current sensor 22 includes a bus-bar-securing part 28, which is different from the bus-bar-securing part 16 of the current sensor 10 in including a projection 28c. The projection 28c projects in the Y direction, in which the bus bar 11 extends, and to the outside of the case 14. The bus-bar-securing part 28 is insert-molded in the case 14 and includes the embedded portion 16a and the fixing surface 16b, which is the same as in the current sensor 10. The projection 28c is a portion of the fixing surface 16b that extends on the outside of the case 14. The bus bar 11 is fixed to the projection 28c of the bus-bar-securing part 28 by welding.

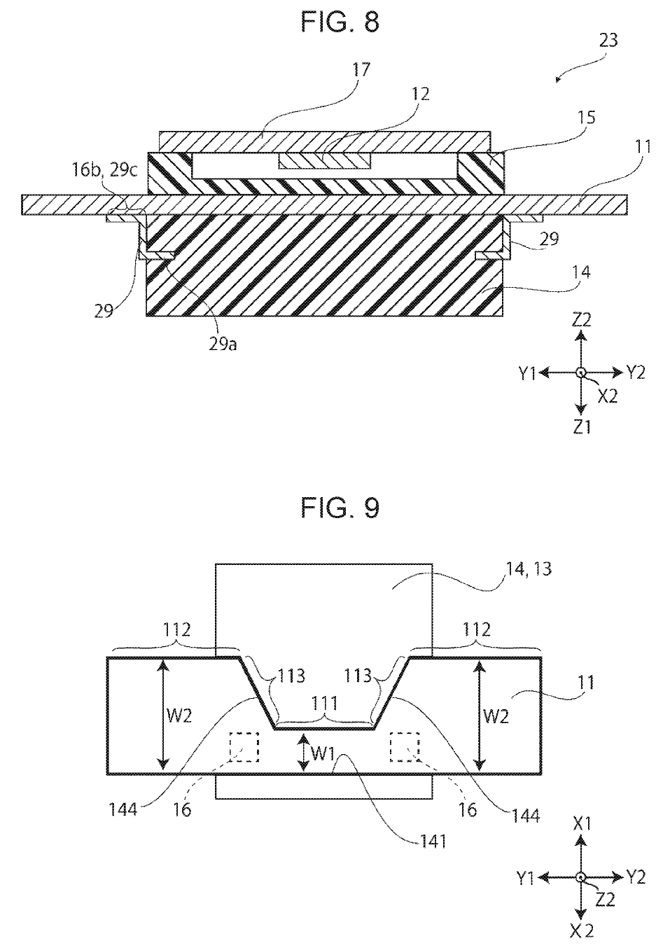

FIG. 8 is a sectional view schematically illustrating a current sensor 23, which is a modification of the current sensor 22 illustrated in FIG. 7. As illustrated in the drawing, the current sensor 23 includes a bus-bar-securing part 29, which is different from the bus-bar-securing part 28 of the current sensor 22 in that the entirety of the fixing surface 16b serves as a projection 29c and in that an embedded portion 29a extends in the Y direction. The bus-bar-securing part 29 is insert-molded in the case 14, which is the same as in the current sensor 20.

The bus-bar-securing parts 28 and 29 include the respective projections 28c and 29c projecting to the outside of the case 14. The bus bar 11 and the bus-bar-securing part 28 or 29 are welded to each other at the corresponding projection 28c or 29c. Thus, heat that is generated at the time of welding is released to the outside of the case 14 through the projection 28c or 29c. Accordingly, the risk of deformation of the case 14 with the heat generated at the time of welding is reduced.

Moreover, at the time of welding, heat (generated by laser application, for example) can be applied from either side in the Z direction. Such selectability in the direction of heat application increases the ease of production. Compared with the configuration of the current sensor 10 illustrated in FIG. 4 and the current sensor 20 illustrated in FIG. 5A, the positional relationship between the bus bar 11 and the bus-bar-securing part 28 (projection 28c or 29c) is visible. Such a configuration facilitates the adjustment and recognition of the point of heat application for welding, and increases the ease of production.

FIG. 9 is a plan view schematically illustrating a fitting structure between the bus bar 11 and the case 14 included in the current sensor 10 illustrated in FIG. 4. As illustrated in the drawing, the case 14 included in the housing 13 has the groove 141 shaped in conformity with the external shape of the bus bar 11 when viewed in the Z direction, in which the bus bar 11 and the magnetic sensor 12 overlap each other (see FIGS. 3 and 4). With the bus bar 11 and the groove 141 fitted to each other, the bus bar 11 is fixed to the bus-bar-securing part 16.

The situation where the case 14 has the groove 141 shaped in conformity with the external shape of the bus bar 11 refers to a situation where the groove 141 whose shape is the same as the external shape of the bus bar 11 is provided in the surface of the case 14 that faces the bus bar 11, so that the bus bar 11 and the groove 141 are fittable to each other. Being shaped in conformity implies that the groove 141 is formed with some allowance with respect to the external shape of the bus bar 11 so that the bus bar 11 is fittable thereto.

The bus bar 11 may include a narrowed portion 111, which has a width dimension W1 (first width dimension); and a widened portion 112, which has a width dimension W2 (second width dimension) that is greater than the width dimension W1 (W2 > W1). In the Y direction in which the bus bar 11 extends, the widened portion 112 may be located on both sides of the narrowed portion 111. The widened portions 112 are connected to the narrowed portion 111 via respective transitional portions 113. The groove 141 of the case 14 may have restricting portions 144, which are to be in contact with the respective transitional portions 113.

The bus bar 11 is fitted into the groove 141 of the case 14 such that the transitional portions 113 of the bus bar 11 and the restricting portions 144 of the groove 141 are brought into contact with each other, whereby the movement of the bus bar 11 in the Y direction in which the bus bar 11 extends is restricted.

Fitting the groove 141 of the case 14 and the bus bar 11 to each other brings the bus bar 11 to a predetermined position relative to the case 14 in the X direction and in the Y direction. That is, providing the groove 141 described above to the case 14 facilitates the positioning of the bus bar 11 relative to the case 14. Specifically, with the bus bar 11 fitted in the groove 141 of the case 14, the bus bar 11 and the bus-bar-securing part 16 provided in the groove 141 are welded to each other. Thus, the bus bar 11 is easily secured to a predetermined position of the case 14.

### Modifications

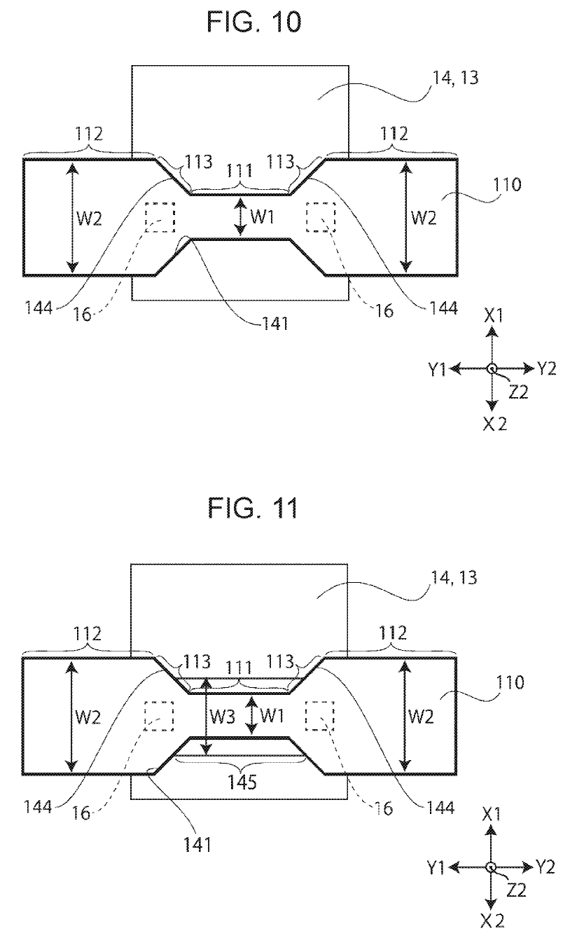

FIG. 10 is a plan view schematically illustrating a modification of the fitting structure illustrated in FIG. 9. A bus bar 110, illustrated in FIG. 10, is configured the same as the bus bar 11 illustrated in FIG. 9, except the position of the narrowed portion 111. Fitting the bus bar 110 illustrated in FIG. 10 into the groove 141 of the case 14 positions the bus bar 110 relative to the case 14.

FIG. 11 is a plan view schematically illustrating another modification of the fitting structure illustrated in FIG. 9. In the plan view, that is, when the groove 141 of the case 14 in which the bus bar 110 is fitted is viewed in the Z direction, a narrowed-portion-placing part 145, which is included in the groove 141 and where the narrowed portion 111 is to be placed, may have a width dimension W3 (third width dimension) that is greater than the width dimension W1 of the narrowed portion 111. If the width dimension W3 of the narrowed-portion-placing part 145 of the groove 141 is set greater than the width dimension W1 of the narrowed portion 111 (W3 > W1), a gap is produced between the narrowed portion 111 and the narrowed-portion-placing part 145. Even in such a case, bringing the transitional portions 113 and the respective restricting portions 144 into contact with each other positions the bus bar 110 relative to the case 14.

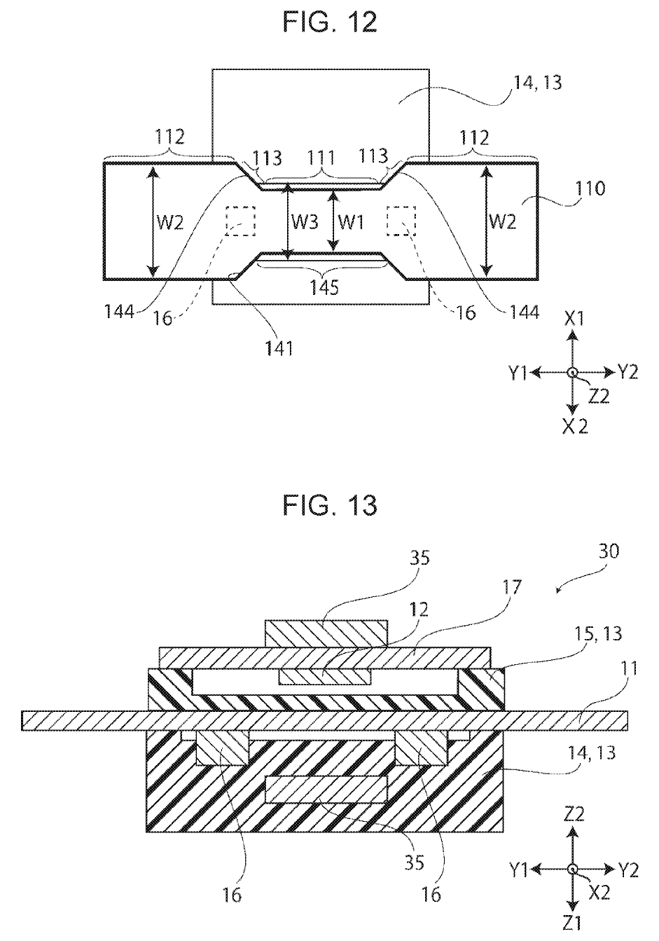

FIG. 12 is a plan view schematically illustrating a state where a bus bar 110 including a narrowed portion 111 having another width dimension W1 is placed in the case 14 illustrated in FIG. 11. As illustrated in the drawing, the case 14 the same as the one illustrated in FIG. 11 is applicable to a bus bar 110 including a narrowed portion 111 having a width dimension W1 that is smaller than the width dimension W3 of the narrowed-portion-placing part 145.

That is, a single case 14 is applicable to any bus bar 110 as long as the bus bar 110 includes a narrowed portion 111 having a width dimension W1 that is equal to or smaller than the width dimension W3 of the narrowed-portion-placing part 145 (W1 ≤ W3). Thus, the use of a standardized case 14 is enabled for a plurality of kinds of bus bars 110 including narrowed portions 111 having different width dimensions W1. For example, a customer need for a greater measurement-target current can be met simply by changing the bus bar 110 to a one having a greater width dimension W1. That is, various bus bars 110 including narrowed portions 111 having different width dimensions W1 are handleable, which is advantageous in reducing the manufacturing cost of the current sensor.

The lengths of the narrowed portion 111 and the narrowed-portion-placing part 145 in the Y direction may be set such that bringing the transitional portions 113 of the bus bar 110 and the respective restricting portions 144 of the groove 141 into contact with each other positions the bus bar 110 relative to the case 14 in the X direction and in the Y direction.

### Second Embodiment

FIG. 13 is a sectional view schematically illustrating a configuration of a current sensor 30 according to a second embodiment. As illustrated in the drawing, the current sensor 30 is different from the current sensor 10 illustrated in FIG. 4 in that a magnetic shield 35 is insert-molded in the case 14 included in the housing 13. In addition to the magnetic shield 35 insert-molded in the case 14, the current sensor 30 includes another magnetic shield 35, which is provided on the substrate 17 at a surface opposite the surface having the magnetic sensor 12.

The magnetic shield 35 is, for example, a stack of a plurality of plate-shaped metal bodies having the same shape. The magnetic shields 35 suppress magnetic noises to the magnetic sensor 12. Accordingly, the measurement accuracy of the current sensor 30 increases.

While FIG. 13 illustrates a parallel-plate magnetic shield 35 constituted by a pair of magnetic shields 35 between which the bus bar 11 and the magnetic sensor 12 are located, either of the magnetic shields 35 may be do.

### Modifications

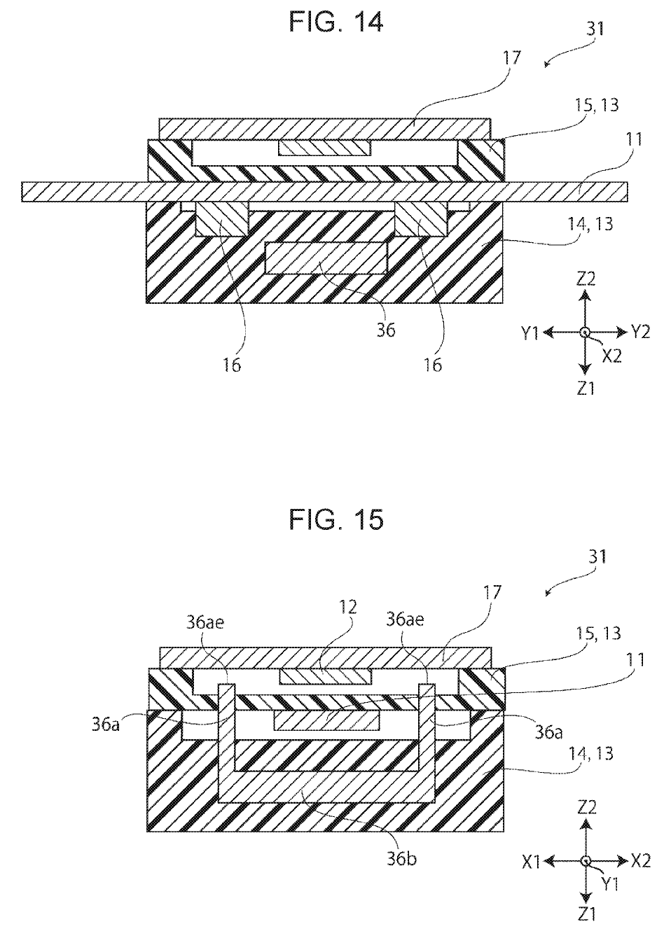

FIG. 14 is a sectional view schematically illustrating a current sensor 31, which is a modification of the current sensor 30 illustrated in FIG. 13. FIG. 15 is a sectional view schematically illustrating the current sensor 31 illustrated in FIG. 14 but seen in another direction. Specifically, FIG. 15 illustrates a section corresponding to a section of the current sensor 10 illustrated in FIG. 2 that is taken along line XV-XV.

The current sensor 31 illustrated in the drawings is different from the current sensor 30 in including a U-shaped magnetic shield 36 in replacement of the parallel-plate magnetic shield 35. The magnetic shield 36 includes side wall portions 36a, which are located on two respective sides in the X direction and are spaced apart from each other; and a bottom portion 36b, which connects the two side wall portions 36a to each other. Accordingly, the magnetic shield 36 has a U shape when viewed in the Y direction.

The bottom portion 36b has a flat plate shape with a plate surface parallel to the XY plane. The bottom portion 36b is located on the Z1 side relative to the bus bar 11 in the Z direction and faces toward the bus bar 11. The side wall portions 36a are each a flat plate having a plate surface parallel to the YZ plane. The side wall portions 36a extend from two respective X-direction ends of the bottom portion 36b toward the Z2 side in the Z direction.

As illustrated in FIG. 15, the magnetic sensor 12 is located near ends 36ae of the magnetic shield 36 but is not located between the side wall portions 36. In such a configuration, the magnetic shield 36 functions as a core and is capable of collecting magnetic flux lines.

The magnetic sensor 12 may be located between the side wall portions 36a of the magnetic shield 36. That is, the magnetic sensor 12 may be located on the Z1 side relative to the ends 36ae of the side wall portions 36a such that the magnetic sensor 12 and the side wall portions 36a of the magnetic shield 36 overlap each other when viewed in the X direction. The magnetic sensor 12 located between the side wall portions 36a enables the magnetic shield 36 to effectively suppress the disturbance of the magnetic field with respect to the magnetic sensor 12.

### Third Embodiment (Reference)

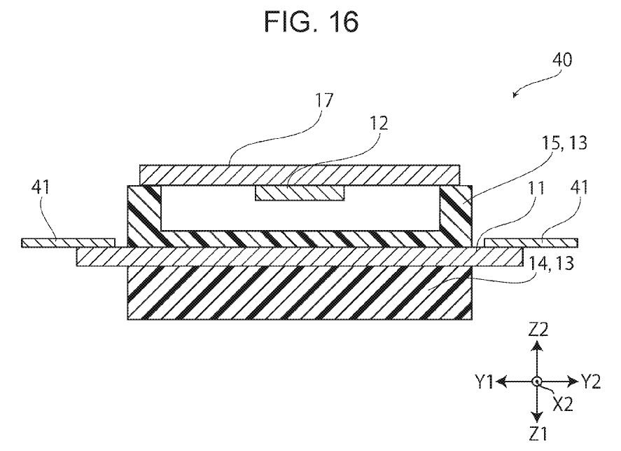

FIG. 16 is a sectional view schematically illustrating a configuration of a current sensor 40 according to a third embodiment. As illustrated in the drawing, the bus bar 11 of the current sensor 40 is insert-molded in the case 14, and extension bus bar parts 41 are welded to respective portions of the bus bar 11 that project to the outside of the case 14. In such a configuration in which the extension bus-bar parts 41 are welded for electrical connection to the bus bar 11 insert-molded in the case 14, an increased degree of freedom is provided to the bus bar 11 in the possible shape thereof outside the case 14, with the shape of the bus bar 11 inside the case 14 being the same.

Insert-molding the bus bar 11 into the case 14 stabilizes the positional relationship between the case 14 and the bus bar 11. Accordingly, the reduction in the measurement accuracy of the current sensor 40 due to the displacement between the bus bar 11 and the case 14 is suppressed. Thus, while a favorable measurement accuracy is maintained, the degree of freedom in the shape of the bus bar 11 outside the case 14 is increased.

### Industrial Applicability

The present invention is useful as a current sensor configured to measure a measurement-target current flowing through a device, in controlling, for example, a power source system of a vehicle or the like including various devices.

What is claimed is:

1. A current sensor comprising:
a bus bar through which a measurement-target current is to flow;
a magnetic sensor provided facing the bus bar and configured to detect a magnetic force generated by the bus bar; and
a housing including a case and a cover, the bus bar being held between the case and the cover,
wherein the housing includes a bus-bar-securing part made of a metal material,
wherein the bus bar is in contact with the bus-bar-securing part and is fixed to the bus-bar-securing part,
wherein the bus-bar-securing part includes a projection projecting to an outside of the housing in a direction in which the bus bar extends, and
wherein the bus bar is fixed to the projection by welding.

2. The current sensor according to claim 1,
wherein the bus-bar-securing part is included in the case.

3. The current sensor according to claim 1,
wherein the bus-bar-securing part is provided at a plurality of locations of the housing.

4. The current sensor according to claim 1,
wherein the bus-bar-securing part is insert-molded in the housing.

5. The current sensor according to claim 4,
wherein the bus-bar-securing part includes an anchor portion.

6. The current sensor according to claim 1,
wherein a magnetic shield is insert-molded in the case.

7. The current sensor according to claim 1,
wherein the case has a groove shaped in conformity with an external shape of the bus bar when viewed in a direction in which the bus bar and the magnetic sensor overlap each other,
wherein the bus-bar-securing part is located in the groove, and
wherein the bus bar is fixed to the bus-bar-securing part with the bus bar and the groove fitted to each other.

8. The current sensor according to claim 1,
wherein the case has a groove,
wherein the bus-bar-securing part is located in the groove,
wherein the bus bar includes a narrowed portion having a first width dimension; and a widened portion having a second width dimension that is greater than the first width dimension,
wherein, in a direction in which the bus bar extends, the widened portion is provided on both sides of the narrowed portion with transitional portions connecting the respective widened portions and the narrowed portion to each other,
wherein the groove includes restricting portions that are in contact with the respective transitional portions, and
wherein the bus bar is fixed to the bus-bar-securing part with the groove and the bus bar fitted to each other and with the transitional portions and the restricting portions being in contact with each other.

9. The current sensor according to claim 8,
wherein when the groove is viewed in a direction in which the bus bar and the magnetic sensor overlap each other, a width dimension of a narrowed-portion-placing part where the narrowed portion is placed is greater than the width dimension of the narrowed portion.
